(19) United States
(12) Patent Application Publication
(10) Pub. No.: US 2024/0264522 A1
(43) Pub. Date: Aug. 8, 2024

(54) MASK CASE, MASK HANDLING AUTOMATION APPARATUS AND OPERATING METHOD THEREOF

(71) Applicant: Samsung Electronics Co., Ltd., Suwon-si (KR)

(72) Inventors: Yun Song JEONG, Suwon-si (KR); Jun Hyuk CHANG, Suwon-si (KR); Sang Yong YU, Suwon-si (KR); Sang Min KIM, Suwon-si (KR); Jae Sung BYUN, Suwon-si (KR); Hyun Woo LEE, Suwon-si (KR)

(21) Appl. No.: 18/410,463

(22) Filed: Jan. 11, 2024

(30) Foreign Application Priority Data
Feb. 3, 2023 (KR) 10-2023-0014786

(51) Int. Cl. G03F 1/66; G03F 7/00

(52) U.S. Cl. CPC G03F 1/66; G03F 7/70733; G03F 7/70808

(57) ABSTRACT

A mask case includes a lower case including a first side surface and a second side surface opposite each other, a first rail on the first side surface, and a second rail on the second side surface, an upper case separable from the lower case, and includes third and fourth side surfaces corresponding to the first and second side surfaces, a third rail on the third side, and a fourth rail on the fourth side, a first sliding lock member slidable along the first and third rails, and a second sliding lock member slidable along the second and fourth rails, first and second holes for coupling first and second pins of first and second locking open and close devices are in the first and second sliding lock members, and the first and second sliding lock members are slid by the first and second locking open and close devices.

### CROSS-REFERENCE TO RELATED APPLICATION

This application is based on and claims priority under 35 U.S.C. § 119 to Korean Patent Application No. 10-2023-0014786 filed on Feb. 3, 2023 in the Korean Intellectual Property Office, the contents of which in its entirety are herein incorporated by reference.

### BACKGROUND

### 1. Field

The present disclosure relates to a mask case, a mask handling automation apparatus, and an operating method thereof.

### 2. Description of the Related Art

A blank mask is a raw material of a photo mask used in a photolithography process in a semiconductor process. When the blank mask is in a raw material state without circuit patterns formed inside and is stored in a Fab or loaded into an apparatus, in order to eliminate the inconvenience of manual work required to be performed by workers, research is being conducted on a standardized mask case that may be automated, and a method for handling the blank mask stored inside the mask case through an automated process.

### SUMMARY

Aspects of the present disclosure provide a mask case having improved stability and that is suitable for an automation apparatus.

Aspects of the present disclosure also provide a mask handling automation apparatus that handles a mask through an automated process.

Aspects of the present disclosure also provide an operating method of a mask handling automation apparatus that handles masks through the automated process.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In accordance with an aspect of the disclosure, a mask case includes a lower case including a first body including a first side surface and a second side surface opposite each other, a first rail on the first side surface, and a second rail on the second side surface, the first rail including a first portion having a first width, and a second portion connected to the first portion and having a second width greater than the first width, the second rail including a third portion having a third width, and a fourth portion connected to the third portion and having a fourth width greater than the third width; an upper case separable from the lower case, the upper case including a second body including a third side surface corresponding to the first side surface and a fourth side surface corresponding to the second side surface, a third rail on the third side surface and corresponding to the first portion of the first rail, and a fourth rail on the fourth side surface and corresponding to the third portion of the second rail; a first sliding lock member slidable along the first rail and the third rail; and a second sliding lock member slidable along the second rail and the fourth rail, wherein, when the first sliding lock member is located at the second portion of the first rail and the second sliding lock member is located at the fourth portion of the second rail, the upper case and the lower case are unlocked, when the first sliding lock member is located at the first portion of the first rail and at the third rail, and the second sliding lock member is located at the third portion of the second rail and at the fourth rail, the upper case and the lower case are locked, a first hole for coupling a first pin of a first locking open and close device is provided in the first sliding lock member, and the first sliding lock member is configured to be slid by the first locking open and close device, and a second hole for coupling a second pin of a second locking open and close device is provided in the second sliding lock member, and the second sliding lock member is configured to be slid by the second locking open and close device.

In accordance with an aspect of the disclosure, a mask handling automation apparatus includes a lower case including a first body including a first side surface and a second side surface opposite each other, a first rail on the first side surface, and a second rail on the second side surface, the first rail including a first portion having a first width, and a second portion connected to the first portion and having a second width greater than the first width, the second rail including a third portion having a third width, and a fourth portion connected to the third portion and having a fourth width greater than the third width; an upper case separable from the lower case, the upper case including a second body including a third side surface corresponding to the first side surface and a fourth side surface corresponding to the second side surface, a third rail on the third side surface and corresponding to the first portion of the first rail, and a fourth rail on the fourth side surface and corresponding to the third portion of the second rail; a first sliding lock member slidable along the first rail and the third rail; a second sliding lock member slidable along the second rail and the fourth rail; a first locking open and close device including a first pin for reciprocating the first sliding lock member in a first direction; and a second locking open and close device including a second pin for reciprocating the second sliding lock member in the first direction, wherein, when the first sliding lock member is located at the second portion of the first rail and the second sliding lock member is located at the fourth portion of the second rail, the upper case and the lower case are unlocked, when the first sliding lock member is located at the first portion of the first rail and at the third rail, and the second sliding lock member is located at the third portion of the second rail and at the fourth rail, the upper case and the lower case are locked, a first hole for coupling the first pin of the first locking open and close device is provided in the first sliding lock member, and the first sliding lock member is configured to be slid by the first locking open and close device, a second hole for coupling the second pin of the second locking open and close device is provided in the second sliding lock member, and the second sliding lock member is configured to be slid by the second locking open and close device, and the lower case, the upper case, the first sliding lock member, and the second sliding lock member form a mask case.

In accordance with an aspect of the disclosure, an operating method of a mask handling apparatus includes providing the mask handling automation apparatus which includes a lower case including a first body including a first side surface and a second side surface opposite each other, a first rail on the first side surface, and a second rail on the second side surface, the first rail including a first portion having a first width, and a second portion connected to the first portion and having a second width greater than the first width, the second rail including a third portion having a third width, and a fourth portion connected to the third portion and having a fourth width greater than the third width; an upper case separable from the lower case, the upper case including a second body including a third side surface corresponding to the first side surface and a fourth side surface corresponding to the second side surface, a third rail on the third side surface and corresponding to the first portion, and a fourth rail on the fourth side surface and corresponding to the third portion; a first sliding lock member slidable along the first rail and the third rail; a second sliding lock member slidable along the second rail and the fourth rail; a first locking open and close device including a first pin for reciprocating the first sliding lock member in a first direction; a second locking open and close device including a second pin for reciprocating the second sliding lock member in the first direction; a case open and close device configured to open the upper case in an upward direction; a first fork configured to convey a mask accommodated in the lower case and the upper case to the outside of the lower case; and a second fork configured to convey the lower case coupled with the upper case; releasing locking between the upper case and the lower case by, using the first locking open and close device and the second locking open and close device, sliding the first sliding lock member and the second sliding lock member, respectively, by inserting the first pin and the second pin into a first hole and a second hole respectively provided in the first sliding lock member and the second sliding lock member; separating the upper case from the lower case, using the case open and close device; conveying the mask to the outside of the lower case, using the first fork; mounting the upper case onto the lower case, using the case open and close device; locking the upper case and the lower case by sliding the first sliding lock member and the second sliding lock member by inserting the first pin into the first hole and the second pin into the second hole, using the first locking open and close device and the second locking open and close device, respectively; and conveying the lower case locked with the upper case, using the second fork.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example diagram for explaining a mask case according to some embodiments.

FIG. 2 is an example diagram showing a state in which a lower case and an upper case of the mask case shown in FIG. 1 are separated.

FIG. 3 is an example plan view of the mask case shown in FIG. 1.

FIG. 4 is an example bottom view of the mask shown in FIG. 1.

FIG. 5 is an example diagram of the lower case according to some embodiments.

FIGS. 6 and 7 are example side views of the mask case according to some embodiments.

FIG. 8 is an enlarged view of region I of FIG. 5.

FIG. 9 is an example diagram showing a state in which the mask is seated in the lower case of FIG. 5.

FIG. 10 is an example diagram of an upper case according to some embodiments.

FIGS. 11 to 14 are example side views of a mask case according to some embodiments.

FIG. 15 is an example diagram of a mask handling automation apparatus according to some embodiments.

FIG. 16 is an example diagram for explaining the support plate shown in FIG. 15.

FIG. 17 is a flow chart for explaining an operating method of a mask handling automation apparatus according to some embodiments.

FIGS. 18 to 34 are intermediate step diagrams for explaining the operating method of the mask handling automation apparatus according to some embodiments.

### DETAILED DESCRIPTION OF THE EMBODIMENTS

A mask case, a mask handling automation apparatus, and an operating method thereof according to some embodiments will be described below with reference to the accompanying drawings.

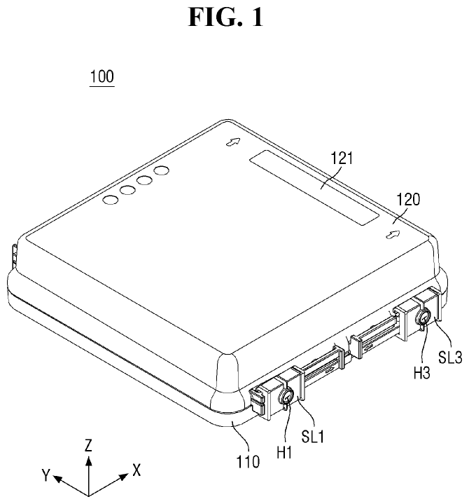

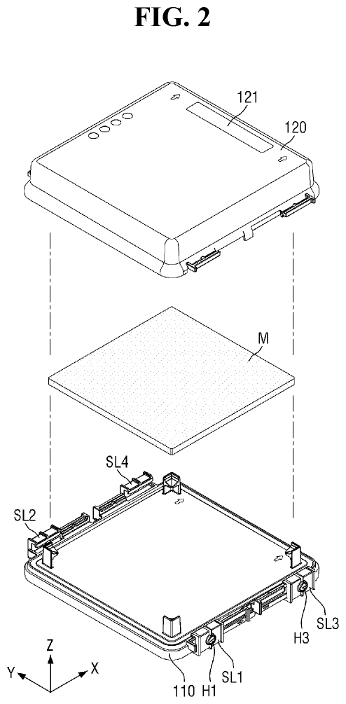

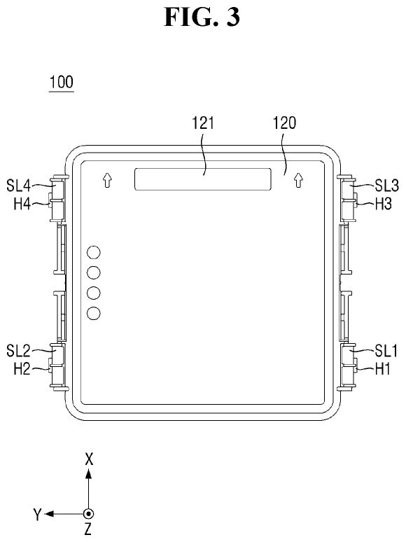

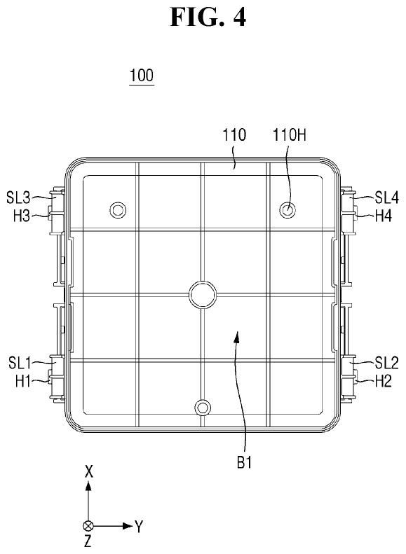

FIG. 1 is an example diagram for explaining a mask case according to some embodiments. FIG. 2 is an example diagram showing a state in which a lower case and an upper case of the mask case shown in FIG. 1 are separated. FIG. 3 is an example plan view of the mask case shown in FIG. 1. FIG. 4 is an example bottom view of the mask shown in FIG. 1. A mask case according to some embodiments will be described below with reference to FIGS. 1 to 4.

A mask case 100 according to some embodiments may include a lower case 110, an upper case 120, and sliding lock members SL1 to SL4. The mask case 100 may include the lower case 110 on which the mask M is seated, and the upper case 120 mounted onto the lower case 110 to cover the mask M seated on the lower case 110. The mask M is a blank mask on which no pattern is formed, and may be a raw material of a photo mask. The mask M may include quartz (SiO₂), and may be provided in the form of a flat rectangular plate.

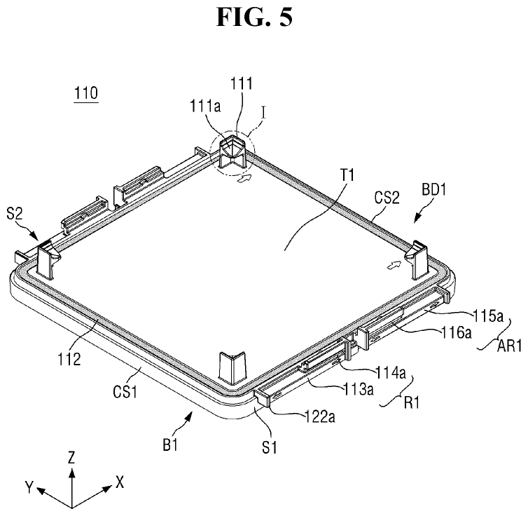

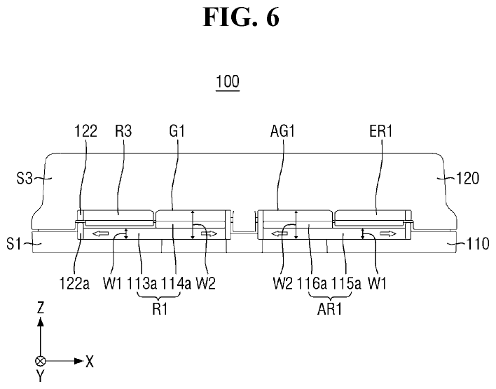

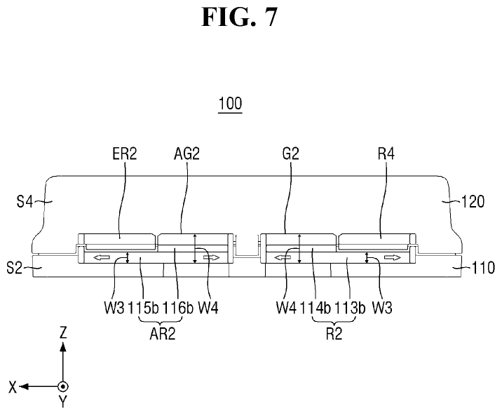

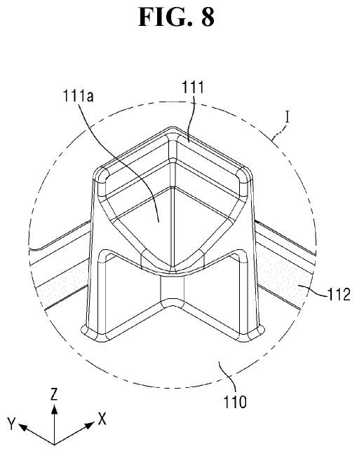

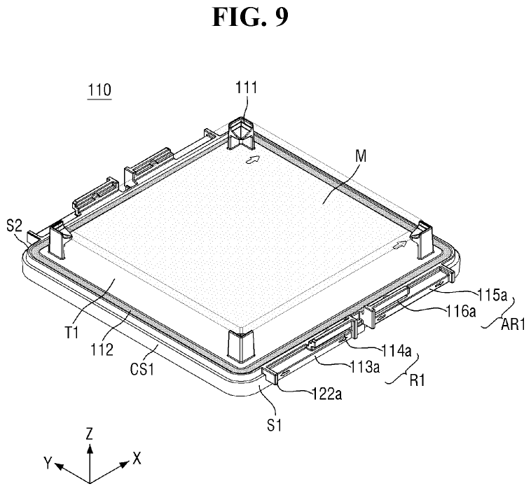

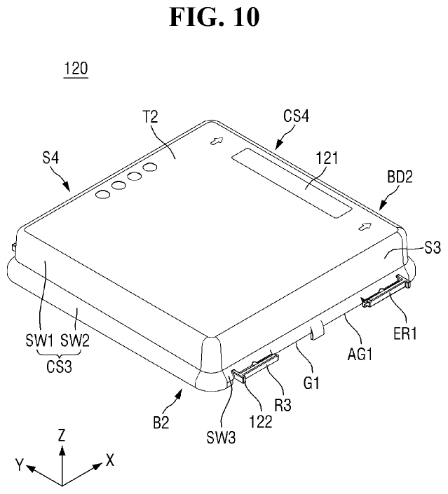

FIG. 5 is an example diagram of the lower case according to some embodiments. FIGS. 6 and 7 are example side views of the mask case according to some embodiments. FIG. 8 is an enlarged view of region I of FIG. 5. FIG. 9 is an example diagram showing a state in which the mask is seated on the lower case of FIG. 5. FIG. 10 is an example diagram of an upper case according to some embodiments. The lower case and the upper case according to some embodiments will be described below with reference to FIGS. 5 to 10.

Referring to FIG. 5, the lower case 110 may include a body BD1 including a side surface S1 and a side surface S2 that are opposite each other and extend in a first direction X. The body BD1 may include a connecting surface CS1 that connects the side surfaces S1 and S2, and may include a connecting surface CS2 that is opposite the connecting surface CS1 and extend in a second direction Y. The body BD1 may include a lower surface B1 (which may correspond to a bottom surface of the mask case 100 shown in FIG. 4) that connects the side surfaces S1 and S2, and an upper surface T1 that is opposite to the lower surface B1 in a third direction Z. The body BD1 of the lower case 110 may be provided in a rectangular shape.

FIG. 6 is a diagram showing side surface S1 in a state in which the upper case 120 is mounted onto the lower case 110, and is a diagram showing a state in which the sliding lock members SL1 and SL3 are removed from the mask case 100 for convenience of explanation. Referring to FIG. 6, a rail R1 may be provided on the side surface S1 of the lower case 110. The rail R1 may be divided into a first portion 113a and a second portion 114a. The first portion 113a may have a first width W1 in the third direction Z. The second portion 114a may be formed to be connected to the first portion 113a, and may have a second width W2 in the third direction Z. The second width W2 of the second portion 114a may be greater than the first width W1 of the first portion 113a. That is, the second portion 114a may be formed to protrude beyond the first portion 113a in the third direction Z.

In some embodiments, an auxiliary rail AR1 may be installed on the side surface S1 of the lower case 110 to be adjacent to the rail R1. The auxiliary rail AR1 may be divided into a fifth portion 115a and a sixth portion 116a. The fifth portion 115a may have the first width W1 in the third direction Z. The sixth portion 116a may be formed to be connected to the fifth portion 115a, and may have the second width W2 in the third direction X. The second width W2 of the sixth portion 116a may be greater than the first width W1 of the fifth portion 115a. That is, the sixth portion 116a may be formed to protrude beyond the fifth portion 115a in the third direction Z. The first portion 113a, the second portion 114a, the sixth portion 116a, and the fifth portion 115a may be disposed on the side surface S1 of the lower case 110 in order along the first direction X. For example, the rail R1 and the auxiliary rail AR1 may be symmetrically formed on the side surface S1 of the lower case 110.

FIG. 7 is a diagram that shows side surface S2 in a state in which the upper case 120 is mounted onto the lower case 110, and is a diagram that shows a state in which the sliding lock members SL2 and SL4 are removed from the mask case 100 for convenience of explanation. Referring to FIG. 7, a rail R2 may be installed on the side surface S2 of the lower case 110. The rail R2 may be divided into a third portion 113b and a fourth portion 114b. The third portion 113b may have a third width W3 in the third Z direction. The fourth portion 114b may be formed to be connected to the third portion 113b, and may have a fourth width W4 in the third direction Z. The fourth width W4 of the fourth portion 114b may be greater than the third width W3 of the third portion 113b. That is, the fourth portion 114b may be formed to protrude beyond the third portion 113b in the third direction Z.

In some embodiments, an auxiliary rail AR2 may be installed on the side surface S2 of the lower case 110 to be adjacent to the rail R2. The auxiliary rail AR2 may be divided into a seventh portion 115b and an eighth portion 116b. The seventh portion 115b may have the third width W3 in the third direction Z. The eighth portion 116b may be formed to be connected to the seventh portion 115b, and may have the fourth width W4 in the third direction Z. The fourth width W4 of the eighth portion 116b may be greater than the third width W3 of the seventh portion 115b. That is, the eighth portion 116b may be formed to protrude beyond the seventh portion 115b in the third direction Z. The third portion 113b, the fourth portion 114b, the eighth portion 116b, and the seventh portion 115b may be disposed on the side surface S2 of the lower case 110 in order along the first direction X. For example, the rail R2 and the auxiliary rail AR2 may be symmetrically formed on the side surface S2 of the lower case 110.

Referring back to FIG. 5, in some embodiments, a supporting pin 111 may be formed on the upper surface T1 of the lower case 110 to protrude from the upper surface T1. The supporting pin 111 may be disposed at each of four corners of the upper surface T1 of the rectangular lower case 110.

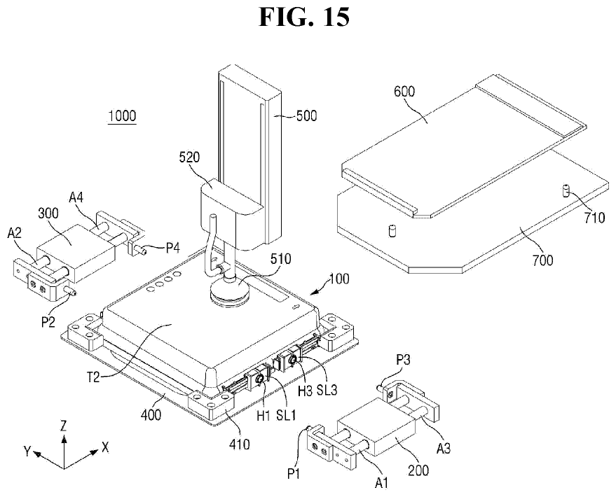

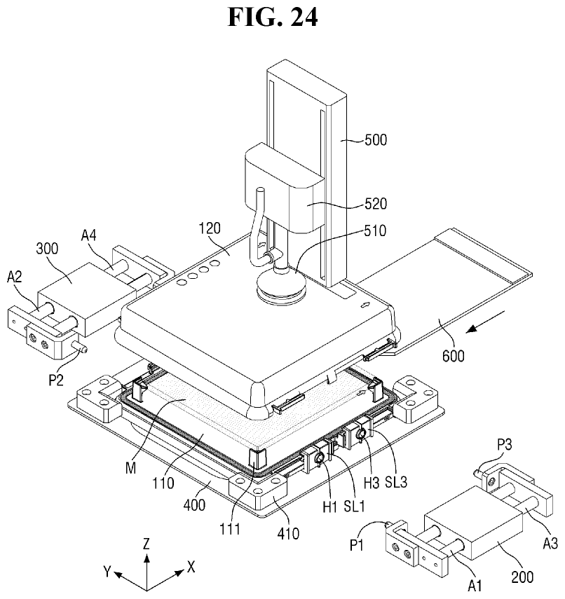

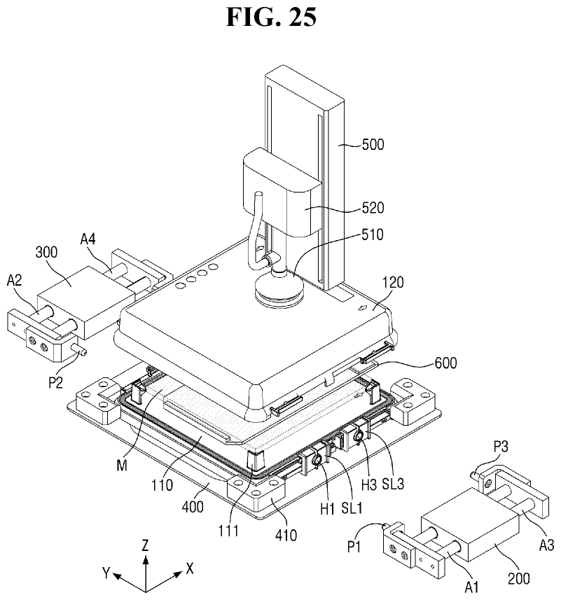

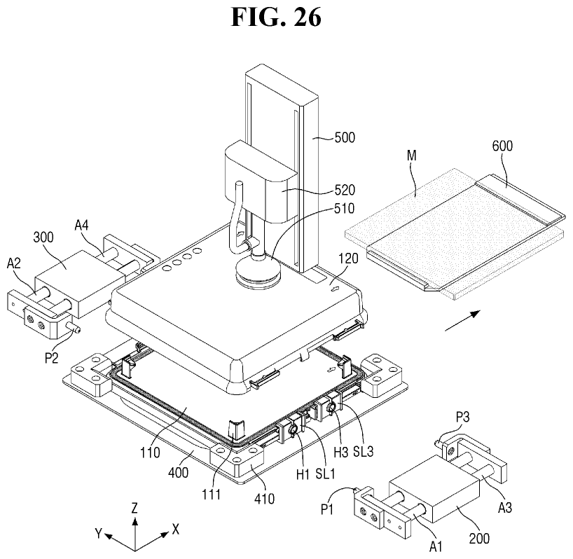

Referring to FIGS. 5, 8 and 9 together, the supporting pin 111 may include seating portions 111a on which edges of the mask M may be seated. The seating portions 111a may be spaced apart from the upper surface T1 in the third direction Z at a constant interval. As a result, in the state in which the upper case 120 is separated from the lower case 110, when the mask M in which the four corners of the mask M are each seated on the seating portions 111a of the supporting pins 111 is to be conveyed outside of the lower case 110, a first fork 600 (shown in FIG. 15) may enter between the lower surface of the mask M and the upper surface T1 of the lower case 110 to convey the mask M to the outside of the lower case 110. An operation of conveying the mask M by the first fork 600 (shown in FIG. 15) will be described below with reference to FIGS. 24 to 26.

In some embodiments, the lower case 110 may include a gasket 112 placed along the edge of the upper surface T1, on the upper surface T1. The gasket 112 may prevent impurity particles from flowing into the mask case 100, maintain the airtightness inside the mask case 100, and improve the dustproof performance of the mask case 100. Therefore, the mask M stored in the mask case 100 may be safely conveyed.

Referring back to FIG. 4, in some embodiments, seating pin holes 110H may be disposed on the lower surface B1 of the lower case 110. Three seating pin holes 110H may be disposed on the lower surface B1 of the lower case 110, and the three seating pin holes 110H may be placed to form a triangle. However, embodiments are not limited thereto, and in some embodiments, four seating pin holes 110H may be formed on the lower surface B1 of the lower case 110, and may be placed to form a rectangle. The number and placement form of the seating pin holes 110H may vary depending on the embodiment.

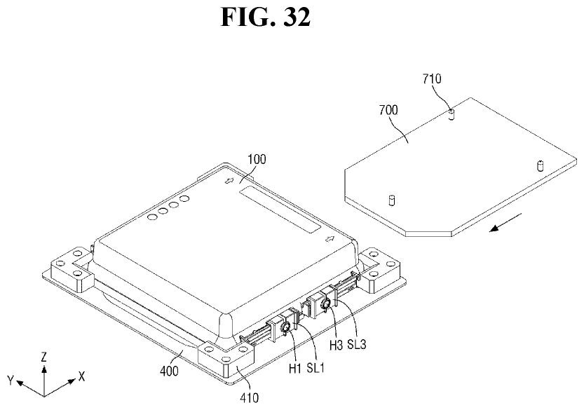

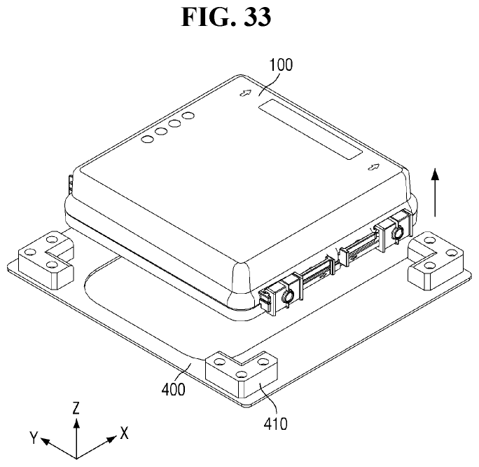

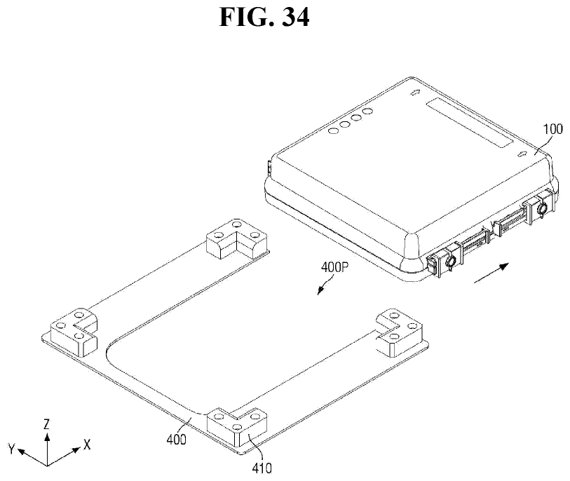

A case fixing pin 710 (shown in FIG. 15) of a second fork 700 (shown in FIG. 15) is inserted into the seating pin hole 110H, so that the mask case 100 may be conveyed in a seated and fixed state. The operation of conveying the mask case 100 by the second fork 700 (shown in FIG. 15) will be described below with reference to FIGS. 32 to 34. The second fork 700 may also be referred to as a robot hand configured to convey the mask case 100.

Referring to FIGS. 6, 7 and 10 together, the upper case 120 may be formed to be separable from the lower case 110. For example, the upper case 120 may be completely detached from the lower case 110. The upper case 120 may include a body BD2 including a side surface S3 and a side surface S4 that are opposite each other and extend in the first direction X. The body BD2 may include a connecting surface CS3 that connects the side surfaces S3 and S4, and may include a connecting surface CS4 that is opposite the connecting surface CS3 and extend in the second direction Y. The body BD2 may include an upper surface T2 that connects the side surfaces S3 and S4, and a lower surface B2 opposite to the upper surface T2 in the third direction Z. The body BD2 of the upper case 120 may be provided in a rectangular shape.

The side surface S3 of the upper case 120 may correspond to the side surface S1 of the lower case 110. Also, the side surface S4 of the upper case 120 may correspond to the side surface S2 of the lower case 110. Accordingly, when the upper case 120 and the lower case 110 are coupled to each other, the side surface S3 of the upper case 120 is disposed on the side surface S1 of the lower case 110, the side surface S4 of the upper case 120 is disposed on the side surface S2 of the lower case 110, and the upper case 120 and the lower case 110 may be locked together.

A rail R3 may be provided on the side surface S3 of the upper case 120 (see, e.g., FIGS. 6 and 10). The rail R3 may correspond to the first portion 113a of the lower case. When the upper case 120 is mounted onto the lower case 110, the rail R3 may be disposed on the first portion 113a, and locked together with the first portion 113a by the sliding lock member SL1.

In some embodiments, a groove G1 may be formed on the side surface S3 of the upper case 120 to be adjacent to the rail R3. The groove G1 may accommodate the second portion 114a formed on the rail R1 of the lower case 110 when the upper case 120 is mounted onto the lower case 110. Additionally, in some embodiments, an auxiliary groove AG1 and an additional rail ER1 may be installed on the side surface S3 of the upper case 120. That is, the rail R3, the groove G1, the auxiliary groove AG1, and the additional rail ER1 may be disposed on the side surface S3 of the upper case 120 in order along the first direction X.

The auxiliary groove AG1 may accommodate the sixth portion 116a formed in the auxiliary rail AR1 of the lower case 110 when the upper case 120 is mounted onto the lower case 110. The additional rail ER1 may correspond to the fifth portion 115a of the lower case 110. When the upper case 120 is mounted onto the lower case 110, the additional rail ER1 may be disposed on the fifth portion 115a and locked together with the fifth portion 115a by the sliding lock member SL3.

A rail R4 may be installed on the side surface S4 of the upper case 120 (see, e.g., FIG. 7). The rail R4 may correspond to the third portion 113b of the lower case 110. When the upper case 120 is mounted onto the lower case 110, the rail R4 may be disposed on the third portion 113b and locked together with the third portion 113b by the sliding lock member SL2.

In some embodiments, a groove G2 may be formed on the side surface S4 of the upper case 120 to be adjacent to the rail R4. The groove G2 may accommodate the fourth portion 114b formed on the rail R2 of the lower case 110 when the upper case 120 is mounted onto the lower case 110. Additionally, in some embodiments, an auxiliary groove AG2 and an additional rail ER2 may be installed on the side surface S4 of the upper case 120. That is, the rail R4, the groove G2, the auxiliary groove AG2, and the additional rail ER2 may be disposed on the side surface S4 of the upper case 120 in order along the first direction X.

The auxiliary groove AG2 may accommodate an eighth portion 116b formed in the auxiliary rail AR2 of the lower case 110 when the upper case 120 is mounted onto the lower case 110. The additional rail ER2 may correspond to the seventh portion 115b of the lower case 110. When the upper case 120 is mounted onto the lower case 110, the additional rail ER2 may be disposed on the seventh portion 115b and locked together with the seventh portion 115b by the sliding lock member SLA.

In some embodiments, when the upper case 120 is mounted onto the lower case 110, the connecting surface CS3 of the upper case 120 may include a side wall SW1 disposed on the connecting surface CS1 of the lower case 110 (e.g., positioned above the connecting surface CS1 of the lower case 110), and a side wall SW2 that comes into contact with the connecting surface CS1 of the lower case 110 (e.g., overlapping and positioned outwardly from the connecting surface CS1 of the lower case 110). The side wall SW1 of the upper case 120 may be disposed inside the side wall SW2. Also, the upper case 120 may include a side wall SW3 connected to the side wall SW2 of the connecting surface CS3, on the side surface S3. At this time, the rail R3 may be formed not to protrude beyond an edge of the side wall SW3 that is connected to the side wall SW2. Further, the groove G1 of the upper case 120 may be formed to be recessed from the side wall SW3. As a result, when the mask case 100 is conveyed in a state in which the sliding lock member SL1 is locked to the rail R3 and the first portion 113a of the rail R1 to lock the upper case 120 and the lower case 110, even if the mask case 100 collides with another object, the locked portion of the mask case 100 may be safely protected.

In some embodiments, the upper case 120 may include a first stopper 122 (see, e.g., FIG. 10) which is installed on the rail R3 to define a position of the sliding lock member SL1. Further, the lower case 110 may include a second stopper 122a (see, e.g., FIG. 9) which is installed on the rail R1 to define the position of the sliding lock member SL1. Therefore, when the sliding lock member SL1 slides on the rails R3 and R1 to lock the upper case 120 and the lower case 110 together, the position of the sliding lock member SL1 may be defined so that the sliding lock member SL1 does not slide in a direction opposite to the first direction X beyond the first stopper 122 and the second stopper 122a.

In some embodiments, the upper case 120 may further include a viewing window 121 formed on the upper surface T2. A worker may check whether the mask M is accommodated inside the mask case 100 and the state of the stored mask M and the like through the viewing window 121.

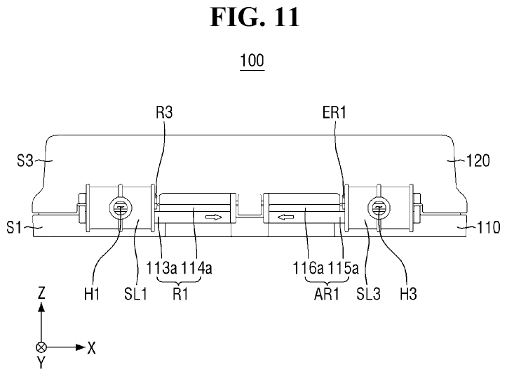

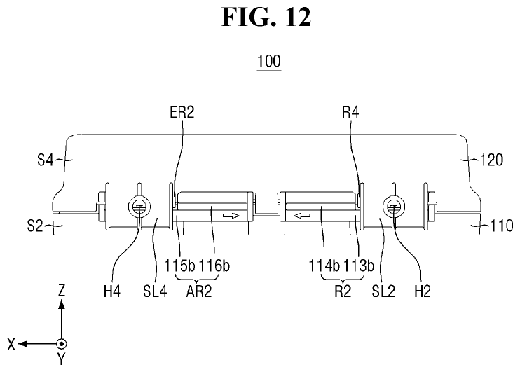

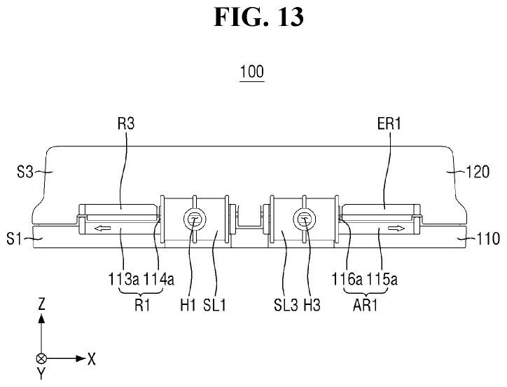

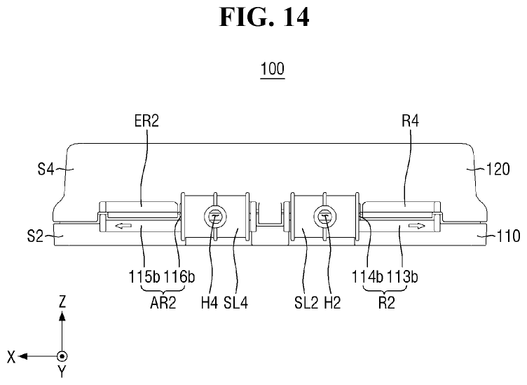

FIGS. 11 to 14 are example side views of a mask case according to some embodiments. FIGS. 11 and 12 are diagrams showing a state in which the lower case 110 and the upper case 120 are locked, and FIGS. 13 and 14 are diagrams showing a state in which the lower case 110 and the upper case 120 are unlocked. The sliding lock members SL1 to SL4 of the mask case according to some embodiments will be described below with reference to FIGS. 11 to 14.

The sliding lock member SL1 may be provided to be slidable along the rails R1 and R3. The sliding lock member SL1 may slide along the rails R1 and R3 to lock or unlock (i.e. release lock) one side portion of the mask case 100 (for example, a contact portion between the side surface S1 of the lower case 110 and the side surface S3 of the upper case 120). Also, the sliding lock member SL2 may be installed to be slidable along the rails R2 and R4. The sliding lock member SL2 may slide along the rails R2 and R4 to lock or unlock the other side portion of the mask case 100 (for example, a contact portion between the side surface S2 of the lower case 110 and the side surface S4 of the upper case 120).

FIGS. 11 and 12 show locked positions of the sliding lock members SL1 and SL2, while FIGS. 13 and 14 show unlocked positions of the sliding lock members SL1 and SL2. For example, as shown in FIG. 11, the sliding lock member SL1 is located at the first portion 113a of the rail R1 and the rail R3 to simultaneously lock the first portion 113a and the rail R3, and as shown in FIG. 12, the sliding lock member SL2 is located on the third portion 113b of the rail R2 and the rail R4 to simultaneously lock the third portion 113b and the rail R4. Thus, the upper case 120 and the lower case 110 may be locked together. Also, as shown in FIG. 13, the sliding lock member SL1 is located at the second portion 114a of the rail R1, and as shown in FIG. 14, the sliding lock member SL2 is located at the fourth portion 114b of the rail R2. Thus, the upper case 120 and the lower case 110 may be unlocked, and separated from each other.

In order to lock or unlock the upper case 120 and the lower case 110 in this manner, the sliding lock member SL1 may be provided with holes H1 for reciprocating the sliding lock member SL1 in the first direction X along the rails R1 and R3. For example, a pin P1 of the first locking open close device 200 (shown in FIG. 15) is inserted into the hole H1, and may reciprocate the sliding lock member SL1 in the first direction X along the rails R1 and R3.

Further, a hole H2 for reciprocating the sliding lock member SL2 in the first direction X along the rails R2 and R4 may be installed in the sliding lock member SL2. For example, the pin P2 of the second locking open and close device 300 (shown in FIG. 15) is inserted into the hole H2, and may reciprocate the sliding lock member SL2 in the first direction X along the rails R2 and R4. The first locking open and close device 200 and the second locking open and close device 300 will be described below with reference to FIG. 15.

In this way, the mask case 100 may lock the lower case 110 and the upper case 120 using the sliding lock member SL1 and the sliding lock member SL2 to safely convey the mask M mounted therein. At this time, when the sliding lock members SL1 and SL2 slide to lock or unlock the lower case 110 and the upper case 120, the sliding lock members SL1 and SL2 may be slid, by inserting pins P1 and P2 of the first and second locking open and close devices 200 and 300 into each of the holes H1 and H2 formed in the sliding lock members SL1 and SL2. In this way, the mask handling work may be automated, by locking or unlocking the mask case 100, using the automated locking open and close device without the worker manually sliding the sliding lock members SL1 and SL2.

In some embodiments, a sliding lock member SL3 and a sliding lock member SL4 may be installed in the mask case 100. The sliding lock member SL3 may be installed to be slidable along the auxiliary rail AR1 and the additional rail ER1. The sliding lock member SL4 may be installed to be slidable along the auxiliary rail AR2 and the additional rail ER2.

The sliding lock member SL3 may slide simultaneously with the sliding lock member SL1. For example, the sliding lock member SL3 may operate by the same first locking open and close device 200 (shown in FIG. 15) as the sliding lock member SL1. A hole H3 for reciprocating the sliding lock member SL3 in the first direction X along the auxiliary rail AR1 and the additional rail ER1 may be installed in the sliding lock member SL3. For example, the pin P3 of the first locking open and close device 200 (shown in FIG. 15) is inserted into the hole H3, and may reciprocate the sliding lock member SL3 in the first direction X along the auxiliary rail AR1 and the additional rail ER1.

For example, as shown in FIG. 11, the sliding lock member SL3 may be located on the fifth portion 115a of the auxiliary rail AR1 and the additional rail ER1 to simultaneously lock the fifth portion 115a of the auxiliary rail AR1 and the additional rail ER1, thereby locking the upper case 120 and the lower case 110 together. Alternatively, as shown in FIG. 13, the sliding lock member SL3 may be located at the sixth portion 116a of the auxiliary rail AR1 to unlock the upper case 120 and the lower case 110.

The sliding lock member SL4 may slide simultaneously with the sliding lock member SL2. For example, the sliding lock member SL4 may operate by the same second locking open and close device 300 (shown in FIG. 15) as the sliding lock member SL2. A hole H4 for reciprocating the sliding lock member SLA in the first direction X along the auxiliary rail AR2 and the additional rail ER2 may be provided at the sliding lock member SL4. For example, the pin P4 of the second locking open and close device 300 is inserted into the hole H4, and may reciprocate the sliding lock member SL4 in the first direction X 1 along the auxiliary rail AR2 and the additional rail ER2.

For example, as shown in FIG. 12, the sliding lock member SL4 may be located on the seventh portion 115b of the auxiliary rail AR2 and the additional rail ER2 to simultaneously lock the seventh portion 115b of the auxiliary rail AR2 and the additional rail ER2, thereby locking the upper case 120 and the lower case 110 together. Alternatively, as shown in FIG. 14, the sliding lock member SL4 may be located at the eighth portion 116b of the auxiliary rail AR2 to unlock the upper case 120 and the lower case 110.

FIG. 15 is an example diagram of a mask handling automation apparatus according to some embodiments.

A mask handling automation apparatus 1000 according to some embodiments may include a mask case 100, a first locking open and close device 200, a second locking open and close device 300, a support plate 400, a case open and close device 500, a first fork 600, and a second fork 700. Hereinafter, repeated explanation of those elements explained above will not be provided, and a difference will be mainly explained.

The first locking open and close device 200 may include an arm A1, an arm A3, a pin P1 connected to the arm A1, and a pin P3 connected to the arm A3. The first locking open and close device 200 may reciprocate in the first direction X, the second direction Y, and the third direction Z. As a result, the first locking open and close device 200 may move such that the pin P1 and the pin P3 are respectively inserted into the hole H1 of the sliding lock member SL1 and the hole H3 of the sliding lock member SL3.

The arm A1 and the arm A3 may operate simultaneously. For example, to lock the upper case 120 and the lower case 110, in the state in which the pin P1 and the pin P3 are inserted into the hole H1 and the hole H3, the arm A1 may move in a direction opposite to the first direction X (as shown, e.g., in FIG. 15), and the arm A2 may move in the first direction X simultaneously. Accordingly, the sliding lock member SL1 may move in a direction opposite to the first direction X, to be located to lock the first portion 113a of the rail R1 and the rail R3. At the same time, the sliding lock member SL3 may move in the first direction X, to be located to lock the fifth portion 115a of the auxiliary rail AR1 and the additional rail ER1.

Further, in the state in which the pins P1 and P3 of the arms A1 and A3 are respectively inserted into the holes H1 and H3 to unlock the upper case 120 and the lower case 110, the arm A1 may move in the first direction X and the arm A3 may move in the direction opposite to the first direction X at the same time. Accordingly, the sliding lock member SL1 may be moved in the first direction X to be located at the second portion 114a of the rail R1. At the same time, the sliding lock member SL3 may move in a direction opposite to the first direction X to be located at the sixth portion 116a of the auxiliary rail AR1.

The second locking open and close device 300 may include an arm A2, an arm A4, a pin P2 connected to the arm A2, and a pin P4 connected to the arm A4. The second locking open and close device 300 may reciprocate in the first X direction, the second Y direction, and the third Z direction. Accordingly, the second locking open and close device 300 may move such that the pin P2 and the pin P4 are each inserted into the holes H2 and H4.

The arm A2 and the arm A4 may operate simultaneously. For example, in the state in which the pin P2 and the pin P4 are respectively inserted into the hole H2 of the sliding lock member SL2 and the hole H4 of the sliding lock member SL4 to lock the upper case 120 and the lower case 110, the arm A2 may move in the direction opposite to the first direction X, and the arm A4 may move in the first direction X at the same time. As a result, the sliding lock member SL2 may be moved in the direction opposite to the first direction X to be located to lock the third portion 113b of the rail R2 and the rail R4. At the same time, the sliding lock member SL4 may move in the first direction X to be located to lock the seventh portion 115b of the auxiliary rail AR2 and the additional rail ER2.

Further, in the state in which the pins P2 and P4 of the arms A2 and A4 are each inserted to the holes H2 and H4 to unlock the upper case 120 and the lower case 110, the arm A2 may move in the first direction X and the arm A4 may move in the direction opposite to the first direction X at the same time. As a result, the sliding lock member SL2 may move in the first direction X to be located on the fourth portion 114b of the rail R2. At the same time, the sliding lock member SL4 may move in a direction opposite to the first direction X to be located on the eighth portion 116b of the auxiliary rail AR2.

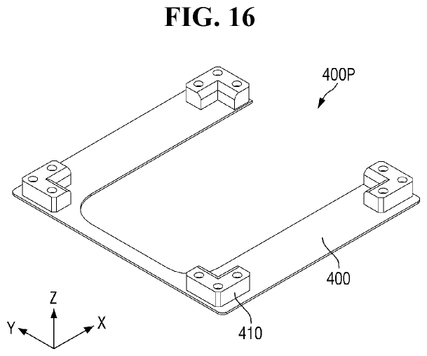

FIG. 16 is an example diagram for explaining the support plate shown in FIG. 15.

Referring to FIGS. 15 and 16 together, the support plate 400 may support the mask case 100. The support plate 400 may be provided in a rectangular form provided with an inlet 400P, and guide members 410 for supporting the mask case 100 may be provided at each corner of the support plate 400. Before the sliding lock members SL1 to SL4 are slid using the first locking open and close device 200 and the second locking open and close device 300, by putting the mask case 100 onto the support plate 400 and seating it to be suitable for the guide member 410 (e.g., positioning the mask case 100 to fit on the guide members 410), the lower case 110 may be fixed onto the support plate 400 at the step of locking or separating the upper case 120 and the lower case 110. Also, the position of the mask case 100 disposed on the support plate 400 may be guided, using the guide member 410.

The inlet 400P of the support plate 400 may be provided at a position corresponding to a side of the mask case 100 at which the first locking open and close device 200 and the second locking open and close device 300 are not installed. In addition, when the mask case 100 is separated from the support plate 400 and conveyed using the second fork 700, the second fork 700 may move to a position underneath the mask case 100 through the inlet 400P (e.g., to a position between the mask case 100 and the support plate 400).

Referring again to FIG. 15, the case open and close device 500 may include a vacuum pad 510, and a vacuum pad movement module 520 connected to the vacuum pad 510. The case open and close device 500 may be disposed above the support plate 400, and convey the upper case 120 in the third direction Z to separate the upper case 120 from the lower case 110, or convey the upper case 120 in the direction opposite to the third direction Z to mount the upper case 120 onto the lower case 110.

The vacuum pad 510 may fix the upper surface T2 of the upper case by vacuum adsorption, and the vacuum pad movement module 520 may reciprocate the vacuum pad 510 in the third direction Z. When the upper case 120 is separated from the lower case 110, the case open and close device 500 fixes the upper surface T2 of the upper case 120 by vacuum adsorption using the vacuum pad 510, and may move the vacuum pad movement module 520 in the third direction Z to separate the upper case 120 from the lower case 110 fixed to the support plate 400. In addition, the case open and close device 500 may move the upper case 120 fixed to the vacuum pad 510 in the direction opposite to the third direction Z using the vacuum pad movement module 520 to couple the upper case 120 to the lower case 110, when the upper case 120 is mounted onto the lower case 110 again.

The first fork 600 may convey the mask M seated on the seating portion 111a of the lower case 110 to the outside of the lower case 110. The first fork 600 enters between the lower surface of the mask M and the upper surface T1 of the lower case 110, fixes the mask M onto the first fork 600, and conveys it to the outside of the lower case 110.

The second fork 700 may separate the mask case 100 from the support plate 400 and convey it with the lower case 110 and the upper case 120 locked together. A case fixing pin 710 may be formed on the upper surface of the second fork 700. The number and placement form of the case fixing pins 710 may correspond to the number and placement form of the seating pin holes 110H formed on the bottom surface of the lower case 110. Therefore, the number and placement form of the case fixing pins 710 formed on the upper surface of the second fork 700 may vary depending on the embodiment. For example, when three seating pin holes 110H are placed in a triangular shape on the bottom surface of the lower case 110, the case fixing pins 710 formed on the upper surface of the second fork 700 may be installed as three case fixing pins 710 forming a triangular shape to correspond thereto.

When conveying the mask case 100 with the lower case 110 and the upper case 120 locked together, the second fork 700 enters the inlet 400P of the support plate 400, inserts the case fixing pin 710 into the seat pin hole 110H, seats and fixes the mask case 100 onto the second fork 700, and may separate the mask case 100 from the support plate 400 and convey it to the outside of the support plate 400.

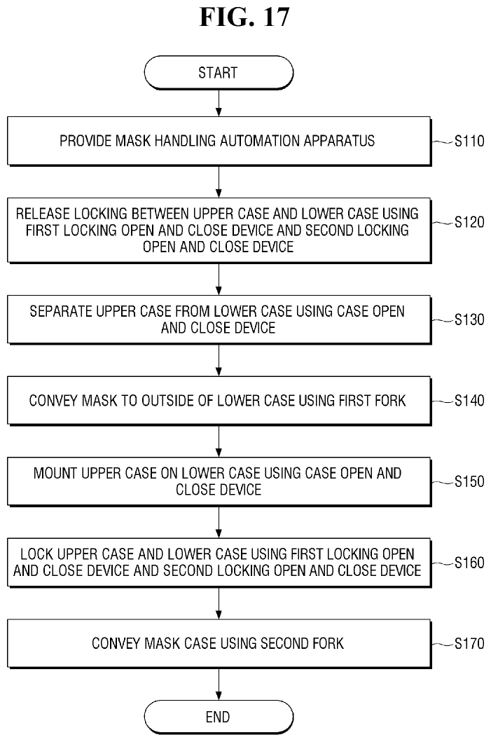

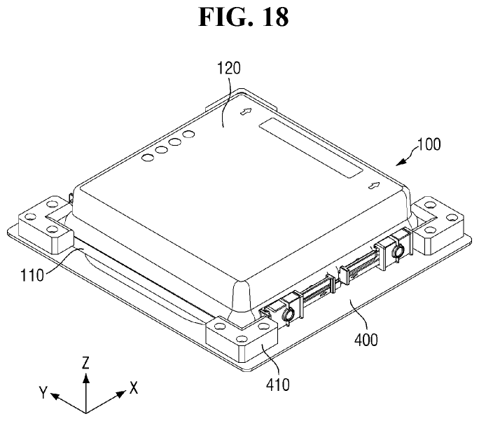

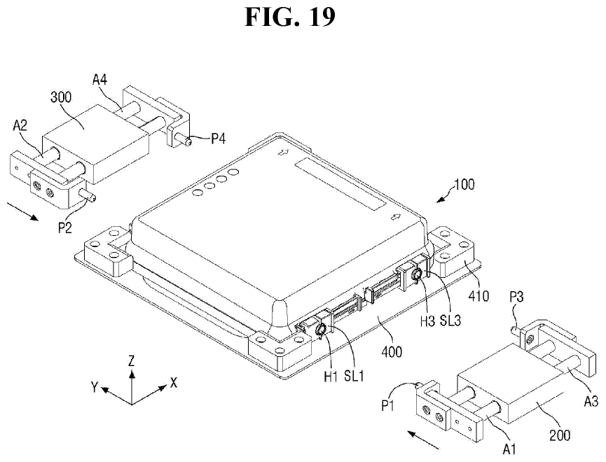

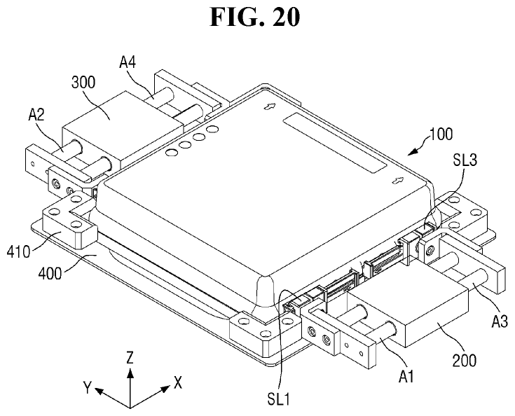

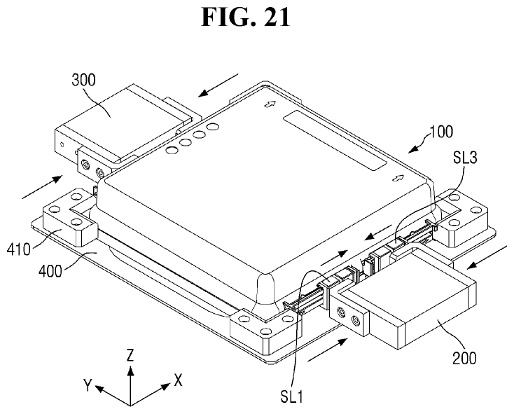

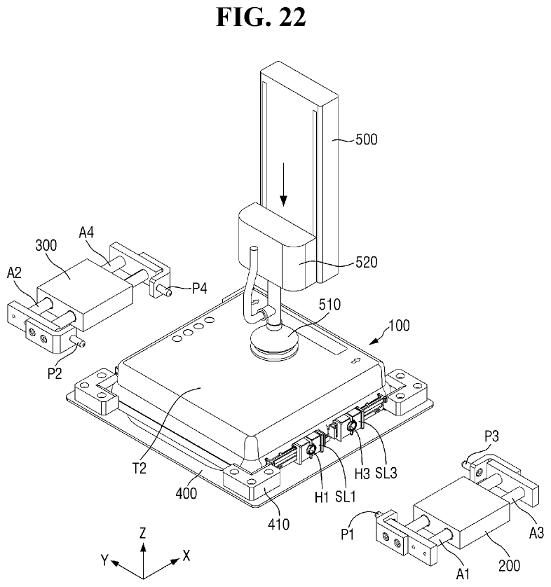

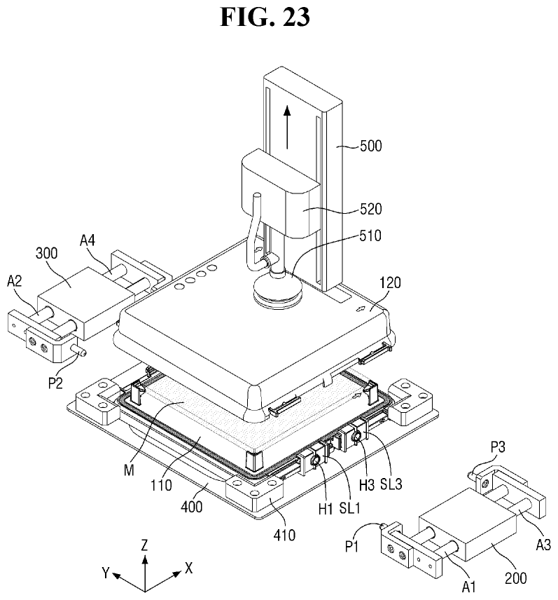

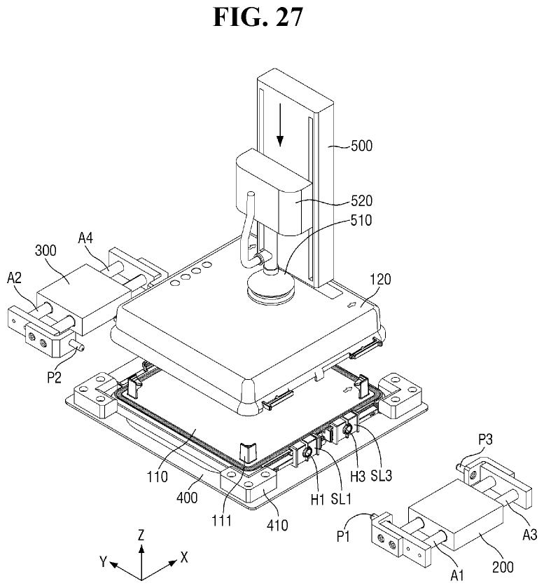

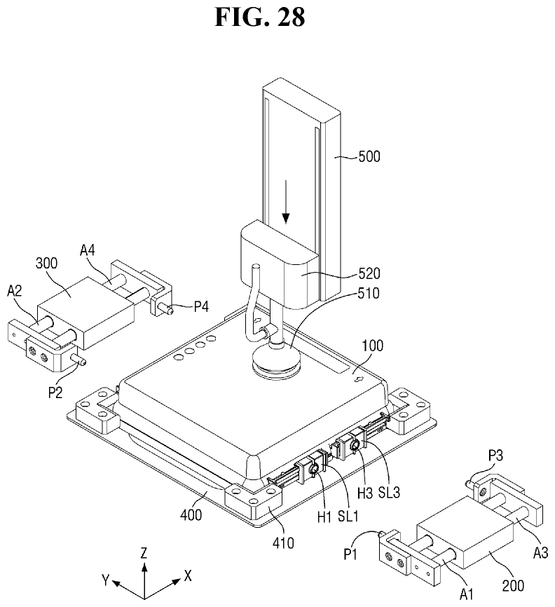

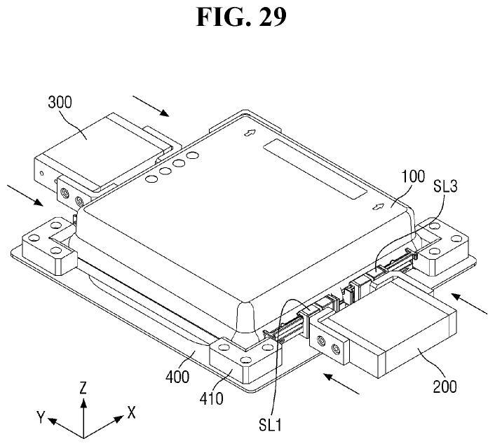

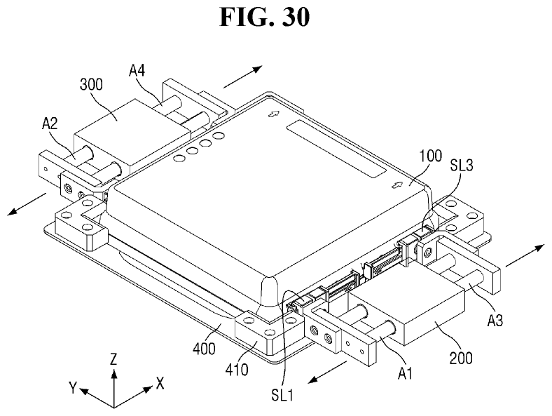

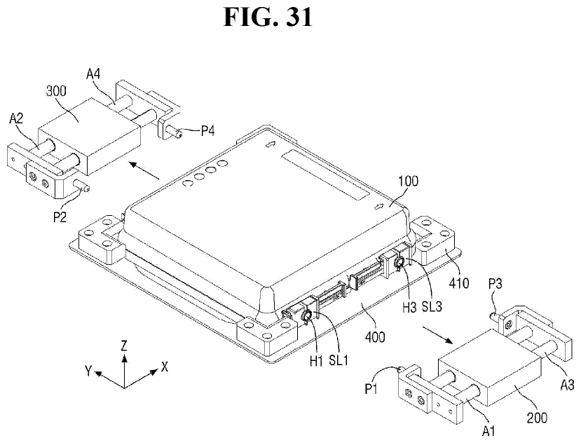

FIG. 17 is a flow chart for explaining an operating method of a mask handling automation apparatus according to some embodiments. FIGS. 18 to 34 are intermediate step diagrams for explaining the operating method of the mask handling automation apparatus according to some embodiments. The operating method of the mask handling automation apparatus according to some embodiments will be described below with reference to FIGS. 17 to 34.

First, a mask handling automation apparatus is provided (S110). The mask handling automation apparatus to be provided may be the mask handling automation apparatus 1000 shown in FIG. 15. At this time, as shown in FIG. 18, the mask case 100 with the upper case 120 and the lower case 110 locked may be fixed on the support plate 400 and provided to be suitable for the guide member 410. For example, the mask case 100 may be positioned to fit in between the guide members 410 on the support plate 400.

Next, referring to FIGS. 17 and 19 to 21, the upper case 120 and the lower case 110 may be unlocked (e.g., locking between the upper case 120 and the lower case 110 may be released), using the first locking open and close device 200 and the second locking open and close device 300 (S120). The pin P1 of the first locking open and close device 200 is inserted into the hole H1 of the sliding lock member SL1, and the arm A1 may move in the first direction X. Therefore, the sliding lock member SL1 may be slid in the first direction X so that the sliding lock member SL1 is located on the second portion 114a of the rail R1. Also, the pin P3 of the first locking open and close device 200 may be inserted into the hole H3 of the sliding lock member SL3 to move the arm A3 in the direction opposite to the first direction X. Therefore, the sliding lock member SL3 may be slid in the direction opposite to the first direction X so that the sliding lock member SL3 is located on the sixth portion 116a of the auxiliary rail AR1.

At the same time, the pin P2 of the second locking open and close device 300 may be inserted into the hole H2 of the sliding lock member SL2, and the arm A2 may be moved in the first direction X. Therefore, the sliding lock member SL2 may be slid in the first direction X so that the sliding lock member SL2 is located on the fourth portion 114b of the rail R2. Further, the pin P4 of the second locking open and close device 300 may be inserted into the hole H4 of the sliding lock member SLA, and the arm A4 may be moved in the direction opposite to the first direction X. Therefore, the sliding lock member SL4 may be slid in the direction opposite to the first direction X so that the sliding lock member SL4 is located at the eighth portion 116b of the auxiliary rail AR2.

Next, referring to FIGS. 17, 22 and 23, the upper case 120 may be separated from the lower case 110, using the case open and close device 500 (S130). The vacuum pad movement module 520 is moved in the direction opposite to the third direction Z so that the vacuum pad 510 comes into contact with the upper surface T2 of the upper case 120, and the vacuum adsorption is performed so that the upper surface T2 of the upper case 120 is fixed to the vacuum pad 510. After that, the vacuum pad movement module 520 may be moved in the third direction Z to separate the upper case 120 from the lower case 110. At this time, since the lower case 110 is in the state of being fixed to the support plate 400 by the guide member 410, the upper case 120 may be completely separated from the lower case 110.

Next, referring to FIGS. 17 and 24 to 26, the mask M may be conveyed to the outside of the lower case 110 using the first fork 600 (S140). At this time, the first fork 600 may enter through a portion of the side portion of the mask case 100 in which the first locking open and close device 200 and the second locking open and close device 300 are not installed. In addition, the first fork 600 may enter between the lower surface of the mask M seated on the seating portion 111a spaced apart from the upper surface T1 of the lower case 110 and the upper surface T1 of the lower case 110 to convey the mask M to the outside of the lower case 110.

Next, referring to FIGS. 17, 27 and 28, the upper case 120 may be mounted onto the lower case 110 using the case open and close device 500 (S150). The vacuum pad movement module 520 is moved in the direction opposite to the third direction Z, the upper case 120 is put on the lower case 110, and the adsorption of the vacuum pad 510 may be released to mount the upper case 120 onto the lower case 110.

Next, referring to FIGS. 17 and 29 to 31, the upper case 120 and the lower case 110 may be locked together, using the first locking open and close device 200 and the second locking open and close device 300 (S160). The pin P1 of the first locking open and close device 200 may be inserted into the hole H1 of the sliding lock member SL1, and the arm A1 may be moved in the direction opposite to the first direction X. As a result, the sliding lock member SL1 is located on the first portion 113a of the rail R1 and the rail R3, and the sliding lock member SL1 may be slid in the direction opposite to the first direction X to simultaneously lock the first portion 113a and the rail R3. Further, the pin P3 of the first locking open and close device 200 may be inserted into the hole H3 of the sliding lock member SL3, and the arm A3 may be moved in the first direction X. As a result, the sliding lock member SL3 is located on the fifth portion 115a of the auxiliary rail AR1 and the additional rail ER1, and the sliding lock member SL3 may be slid in the first direction X to simultaneously lock the fifth portion 115a and the additional rail ER1.

At the same time, the pin P2 of the second locking open and close device 300 may be inserted into the hole H2 of the sliding lock member SL2, and the arm A2 may be moved in the direction opposite to the first direction X. As a result, the sliding lock member SL2 is located on the third portion 113b of the rail R2 and the rail R4, and the sliding lock member SL2 may be slid in the direction opposite to the first direction X to simultaneously lock the third portion 113b and the rail R4. Further, the pin P4 of the second locking open and close device 300 may be inserted into the hole H4 of the sliding lock member SL4, and the arm A4 may be moved in the first direction X. As a result, the sliding lock member SL4 is located on the seventh portion 115b of the auxiliary rail AR2 and the additional rail ER2, and the sliding lock member SL4 may be slid in the first direction X to simultaneously lock the seventh portion 115b and the additional rail ER2.

Next, referring to FIGS. 17 and 32 to 34, the mask case 100, in which the upper case 120 and the lower case 110 are locked, may be conveyed using the second fork 700 (S170). The second fork 700 may enter the inlet 400P of the support plate 400 and insert the case fixing pin 710 into the seating pin hole 110H disposed on the lower surface B1 of the lower case 110 to seat and fix the mask case 100 on the second fork. After that, the second fork 700 may separate the mask case 100 from the support plate 400, and convey the mask case 100 to the outside of the support plate 400.

It will be understood that, although the terms first, second, third etc. may be used herein to describe various elements, devices, components, regions, layers, sections, bodies, surfaces, walls, portions, rails, pins, and/or widths, these elements, components, regions, layers and/or sections should not be limited by these terms. Unless the context indicates otherwise, these terms are only used to distinguish one element, device, component, region, layer, section, body, surface, wall, portion, rail, pin, or width from another, for example as a naming convention. Thus, a first element, device, component, region, layer, section, body, surface, wall, portion, rail, pin, or width discussed below in one section of the specification could be termed a second element, device, component, region, layer, section, body, surface, wall, portion, rail, pin, or width in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Although the embodiments of the present disclosure have been described above with reference to the accompanying drawings, those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A mask case comprising:
a lower case including:
a first body including a first side surface and a second side surface opposite each other,
a first rail on the first side surface, and
a second rail on the second side surface, the first rail including a first portion having a first width, and a second portion connected to the first portion and having a second width greater than the first width, the second rail including a third portion having a third width, and a fourth portion connected to the third portion and having a fourth width greater than the third width;
an upper case separable from the lower case, the upper case including a second body including:
a third side surface corresponding to the first side surface and a fourth side surface corresponding to the second side surface,
a third rail on the third side surface and corresponding to the first portion of the first rail, and
a fourth rail on the fourth side surface and corresponding to the third portion of the second rail;
a first sliding lock member slidable along the first rail and the third rail; and
a second sliding lock member slidable along the second rail and the fourth rail,
wherein, when the first sliding lock member is located at the second portion of the first rail and the second sliding lock member is located at the fourth portion of the second rail, the upper case and the lower case are unlocked,
when the first sliding lock member is located at the first portion of the first rail and at the third rail, and the second sliding lock member is located at the third portion of the second rail and at the fourth rail, the upper case and the lower case are locked,
a first hole for coupling a first pin of a first locking open and close device is provided in the first sliding lock member, and the first sliding lock member is configured to be slid by the first locking open and close device, and
a second hole for coupling a second pin of a second locking open and close device is provided in the second sliding lock member, and the second sliding lock member is configured to be slid by the second locking open and close device.

2. The mask case of claim 1,
wherein the lower case further comprises a first connecting surface that connects the first side surface to the second side surface,
the upper case further comprises a second connecting surface that connects the third side surface to the fourth side surface, and
the second connecting surface comprises a first side wall disposed on the first connecting surface when the upper case is mounted onto the lower case, and a second side wall that is in contact with the first connecting surface when the upper case is mounted onto the lower case such that the first side wall is disposed inside the second side wall when the upper case is mounted onto the lower case.

3. The mask case of claim 2,
wherein the upper case comprises a third side wall on the third side surface, the third side wall being connected to the second side wall of the second connecting surface, and
the third rail does not protrude beyond the third side wall in a direction in which the third side wall extends.

4. The mask case of claim 3,
wherein the upper case comprises a first groove in the third side surface, the first groove being configured to accommodate the second portion of the first rail to be adjacent to the third rail, and
the first groove is recessed beyond the third side wall.

5. The mask case of claim 4,
wherein the lower case further comprises a first auxiliary rail on the first side surface to be adjacent to the first rail,
the first auxiliary rail includes a fifth portion having the first width, and a sixth portion connected to the fifth portion and having the second width greater than the first width,
the first portion, the second portion, the sixth portion, and the fifth portion are disposed in order on the first side surface.

6. The mask case of claim 5,
wherein the upper case further comprises:
a first auxiliary groove on the third side surface, the first auxiliary groove being configured to accommodate the sixth portion of the first auxiliary rail, and
a first additional rail on the third side surface, the first additional rail corresponding to the fifth portion, and
the third rail, the first groove, the first auxiliary groove, and the first additional rail are disposed in order on the third side surface.

7. The mask case of claim 1,
wherein the first body of the lower case comprises a first lower surface that connects the first side surface to the second side surface, and a first upper surface opposite to the first lower surface.

8. The mask case of claim 7,
wherein the lower case further comprises a supporting pin on the first upper surface, and
the supporting pin is at a corner of the first upper surface to protrude from the first upper surface.

9. The mask case of claim 7,
wherein the lower case further comprises a seating pin hole in the first lower surface.

10. A mask handling automation apparatus comprising:
a lower case including:
a first body including a first side surface and a second side surface opposite each other,
a first rail on the first side surface, and
a second rail on the second side surface, the first rail including a first portion having a first width, and a second portion connected to the first portion and having a second width greater than the first width, the second rail including a third portion having a third width, and a fourth portion connected to the third portion and having a fourth width greater than the third width;
an upper case separable from the lower case, the upper case including a second body including:
a third side surface corresponding to the first side surface and a fourth side surface corresponding to the second side surface,
a third rail on the third side surface and corresponding to the first portion of the first rail, and
a fourth rail on the fourth side surface and corresponding to the third portion of the second rail;
a first sliding lock member slidable along the first rail and the third rail;
a second sliding lock member slidable along the second rail and the fourth rail;
a first locking open and close device including a first pin for reciprocating the first sliding lock member in a first direction; and
a second locking open and close device including a second pin for reciprocating the second sliding lock member in the first direction,
wherein, when the first sliding lock member is located at the second portion of the first rail and the second sliding lock member is located at the fourth portion of the second rail, the upper case and the lower case are unlocked,
when the first sliding lock member is located at the first portion of the first rail and at the third rail, and the second sliding lock member is located at the third portion of the second rail and at the fourth rail, the upper case and the lower case are locked,
a first hole for coupling the first pin of the first locking open and close device is provided in the first sliding lock member, and the first sliding lock member is configured to be slid by the first locking open and close device,
a second hole for coupling the second pin of the second locking open and close device is provided in the second sliding lock member, and the second sliding lock member is configured to be slid by the second locking open and close device, and
the lower case, the upper case, the first sliding lock member, and the second sliding lock member form a mask case.

11. The mask handling automation apparatus of claim 10, further comprising:
a support plate which supports the mask case,
wherein the support plate is provided with an inlet for entry of a robot hand configured to convey the mask case.

12. The mask handling automation apparatus of claim 11,
wherein a guide member configured to fix the mask case and guide a position of the mask case is provided at a corner of the support plate.

13. The mask handling automation apparatus of claim 11, comprising:
a case open and close device disposed above the support plate, the case open and close device being configured to be affixed to the upper case and to open the upper case in an upward direction.

14. The mask handling automation apparatus of claim 10,
wherein the first body of the lower case comprises a first lower surface that connects the first side surface to the second side surface, and a first upper surface opposite to the first lower surface.

15. The mask handling automation apparatus of claim 14,
wherein the lower case further comprises a supporting pin on the first upper surface, and
the supporting pin is at a corner of the first upper surface to protrude from the first upper surface.

16. The mask handling automation apparatus of claim 15,
wherein the supporting pin comprises a seating portion on which an edge of a mask accommodated in the mask case is seated, and
the seating portion is spaced apart from the first upper surface of the first body of the lower case.

17. The mask handling automation apparatus of claim 16, further comprising:
a first fork configured to enter between a lower surface of the mask seated on the seating portion and the first upper surface to convey the mask out of the lower case.

18. The mask handling automation apparatus of claim 14,
wherein the lower case further comprises a seating pin hole formed in the first lower surface.

19. The mask handling automation apparatus of claim 18, further comprising:
a second fork comprising a case fixing pin formed on an upper surface of the second fork,
wherein the second fork is configured to insert the case fixing pin into the seating pin hole of the lower case to seat and convey the upper case and the lower case.

20. An operating method of a mask handling automation apparatus, the operating method comprising:
providing the mask handling automation apparatus which includes:
a lower case including:
a first body including a first side surface and a second side surface opposite each other,
a first rail on the first side surface, and
a second rail on the second side surface, the first rail including a first portion having a first width, and a second portion connected to the first portion and having a second width greater than the first width, the second rail including a third portion having a third width, and a fourth portion connected to the third portion and having a fourth width greater than the third width;
an upper case separable from the lower case, the upper case comprising a second body including:
a third side surface corresponding to the first side surface and a fourth side surface corresponding to the second side surface,
a third rail on the third side surface and corresponding to the first portion, and
a fourth rail on the fourth side surface and corresponding to the third portion;
a first sliding lock member slidable along the first rail and the third rail;
a second sliding lock member slidable along the second rail and the fourth rail;
a first locking open and close device including a first pin for reciprocating the first sliding lock member in a first direction;
a second locking open and close device including a second pin for reciprocating the second sliding lock member in the first direction;
a case open and close device configured to open the upper case in an upward direction;
a first fork configured to convey a mask accommodated in the lower case and the upper case to the outside of the lower case; and
a second fork configured to convey the lower case coupled with the upper case;
releasing locking between the upper case and the lower case by, using the first locking open and close device and the second locking open and close device, sliding the first sliding lock member and the second sliding lock member, respectively, by inserting the first pin and the second pin into a first hole and a second hole respectively provided in the first sliding lock member and the second sliding lock member;
separating the upper case from the lower case, using the case open and close device;
conveying the mask to the outside of the lower case, using the first fork;
mounting the upper case onto the lower case, using the case open and close device;
locking the upper case and the lower case by sliding the first sliding lock member and the second sliding lock member by inserting the first pin into the first hole and the second pin into the second hole, using the first locking open and close device and the second locking open and close device, respectively; and
conveying the lower case locked with the upper case, using the second fork.
